(19) United States
(12) Patent Application Publication
(10) Pub. No.: US 2008/0016941 A1
(43) Pub. Date: Jan. 24, 2008

(54) Calibrating Device On A Silicon Substrate

(76) Inventors: Stephane Tisserand, Marseille (FR); Laurent Roux, Marseille (FR); Sophie Jacob, Rousset (FR)

Correspondence Address: Horst M. Kasper, 13 Forest Drive, Warren, NJ, 07059, US

(21) Appl. No.: 11/630,309

(22) PCT Filed: Jun. 23, 2005
(86) PCT No.: PCT/FR05/01582

§ 371 Date: Dec. 20, 2006

(30) Foreign Application Priority Data
Jun. 24, 2004 (FR) 0406912

(51) Int. Cl. G01B 7/34; G01N 27/00; H01J 37/20; H01L 21/66

(52) U.S. Cl. 73/1.89; 427/527

(57) ABSTRACT

The invention relates to a calibration device on a silicon substrate SU formed in addition to a reference level Nc by at least two distinct levels Ng, ND. These levels present distinct doping concentrations. The invention also provides a method of making the calibration device, the method including a definition step for defining at least two sections Sg, Sd distinct from a reference section Sc on a silicon substrate SU. This definition step consists in doping the sections different from the reference section at different concentrations.

The present invention relates to a calibration device on a silicon substrate.

The field of the invention is that of very high accuracy metrology in the context of topographical analysis and of characterizing surface states.

Surface analysis in the broad sense has developed enormously in parallel with the fast development in nanotechnologies. It has progressed further due to the appearance of high performance characterization devices such as the atomic force microscope or the scanning tunneling microscope. Optical metrology also makes use of sophisticated devices, in particular in interferometry, in reflectometry, in diffusometry, and in ellipsometry for measuring infinitesimal dimensions.

Such devices require extremely precise calibration, particularly along the axis Oz that is perpendicular to the surface being analyzed. It is thus known to provide such calibration by means of dimensional standards. One such standard can be a calibrated bead, an etched grating, or any other article for which at least one dimension is known exactly.

The above standards do not provide the accuracy that is now required along the axis Oz, which accuracy must be better than 10 angstroms (Å).

Thus, document FR 2 703 448 proposes a calibration device made form a solution of two polymers in a solvent, that device being in the form of a staircase. Firstly, the shape of the staircase depends on the respective concentrations of the first polymer, of the second polymer, and of the solvent in the solution. Those concentrations are difficult to control, particularly solvent concentration. Solvent concentration will inevitably vary over time between the solution being prepared and being used. Secondly, it is difficult to control the thickness of the solution that is deposited on some substrates. Unfortunately, this thickness has a direct influence on the shape of the staircase. Thirdly, making the device includes a melting step of duration and temperature that must be scrupulously adhered to. It follows that the height of the various steps in the staircase depend on a larger number of parameters that are not always easily reproducible.

Thus, U.S. Pat. No. 5,665,905 teaches a calibration device obtained by welding two silicon substrates face to face, one of the substrates previously being subjected to thermal oxidation. The resulting sandwich is then sawn in a plane that is perpendicular to that of the oxide layer. The plane of cut is then polished. A plateau is made by etching the silicon after initial partial masking, after which a trench is made by etching the oxide following second partial masking. That produces, above the reference level embodied by the surface of the silicon constituting the edge face of the sandwich, two other levels that are distinct, one corresponding to the bottom of the trench and the other to the top of the plateau. Firstly, the mechanical operations necessary for defining the section plane, i.e. sawing and polishing, are operations that are very expensive in the general context of microelectronic processing of silicon wafers. Secondly, the height of the plateau and the depth of the trench relative to the reference level are difficult to know accurately since each of them is the result of a non-selective etching operation. There is no etching stop layer. Thirdly, the width of the plateau and of the trench are limited to the thickness of the thermal oxide layer.

Thus, document EP 0 676 614 discloses a calibration device likewise made on a silicon substrate. A mask in the form of a succession of parallel strips is applied on the substrate presenting a 100 orientation, after which the substrate is subjected to anisotropic etching on 111 oriented planes. This results in V-shaped grooves being formed of width l and of depth p, these two dimensions being related by the equation p 0.706 l. That device does indeed include the equivalent of an etching stop layer since etching of a groove stops when the width of the groove in the top face of the substrate is equal to the gap between the two strips of masks that define the groove. Nevertheless, it follows that the accuracy concerning the depth of the groove depends directly on the accuracy of the mask, which under present circumstances is completely insufficient. Furthermore, that device does not serve to make levels proper, since the bottom of each groove is constituted by a line and not by a plane.

The object of the present invention is thus to provide a calibration device formed by a plurality of levels at dimensions along the axis Oz that are defined very accurately.

According to the invention, a calibration device on a silicon substrate is formed, in addition to a reference level, by at least two distinct levels; in addition, these levels present distinct concentrations of doping.

Optionally, at least one of these levels is surmounted by a step.

Thus, said step consists in a layer that was obtained by thermal growth on said substrate SU.

Preferably, said layer is made of silicon dioxide.

The present invention also provides a method of making a calibration device, the method including a definition step of defining at least two sections that are distinct from a reference section on a silicon substrate; this definition step consists in doping said sections different from said reference section at different concentrations.

Advantageously, said definition step is preceded by a protection step consisting in covering said substrate in a screen.

It is then desirable for said definition step to be followed by a step during which said screen is removed.

In a privileged embodiment, the various sections are doped by ion implantation.

In addition, said definition step is followed by a thermal growth step to produce a coating layer on said substrate.

Optionally, said thermal growth step is followed by a step during which said coating layer is removed.

The present invention appears in greater detail in the following description of embodiments given by way of illustration and with reference to the accompanying figures, in which:

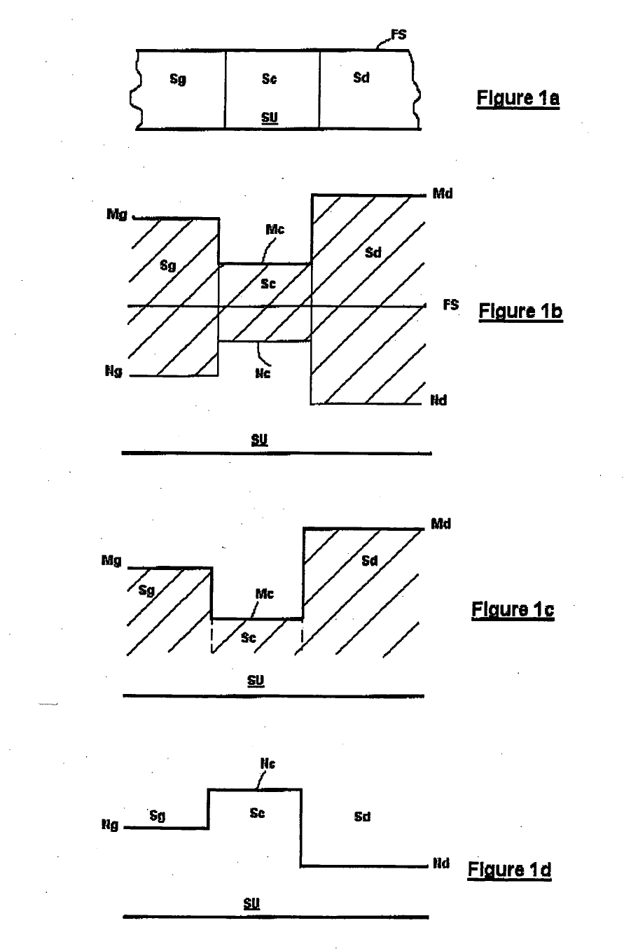

FIG. 1 is a diagram of several variants of a calibration device;

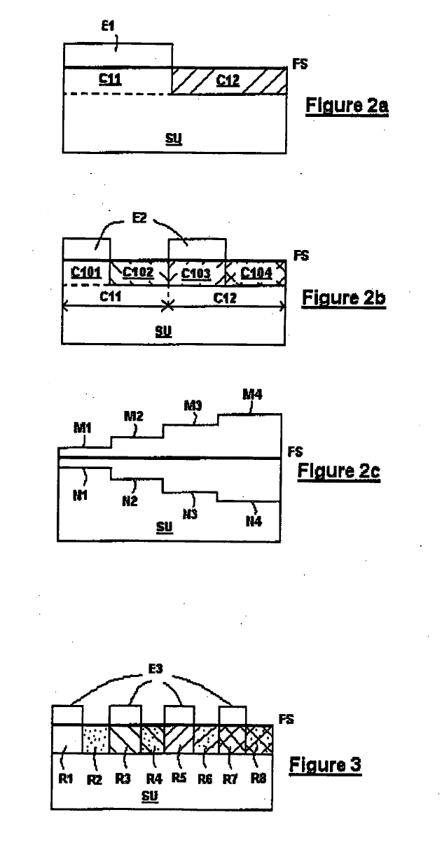

FIG. 2 shows different steps in a method of making such a device; and

FIG. 3 shows an additional step of the method.

Elements that are present in more than one figure are given the same reference in all of them.

With reference to FIG. 1a, the device is made on the top face PS of a silicon substrate SU, The substrate has a left-hand section Sg, a central section Sc, and a right-hand section Sd.

The central section Sc is not doped.

The left-hand section Sg is doped with phosphorus to a concentration of 1.5×10¹⁹ atoms per cubic centimeter (cm⁻³).

The right-hand section Sd in this example is doped with phosphorus to a concentration of 1.5×10²⁰ cm⁻³.

The substrate is subjected to thermal oxidation. The growth rate of the oxide depends on how the silicon is doped, particularly when the oxidation temperature is low. This dependence is not very marked above 1100° C., but it is significant in the range 900° C. to 1000° C.

The table below gives the appropriate thickness of oxide obtained as a function of phosphorus doping and as a function of oxidation time for a temperature of 920° C.;

| | 4.0 × 10¹⁶ cm⁻³ | 3.7 × 10¹⁹ cm⁻³ | 1.5 × 10²⁰ cm⁻³ |
|---|---|---|---|
| 30 min | 140 nm | 170 nm | 220 nm |
| 60 min | 230 nm | 310 nm | 340 nm |
| 150 mn | 470 nm | 530 nm | 630 nm |

Similarly, the tables below show the approximate oxide thickness when the dopant used is boron instead of phosphorus, still as a function of doping concentration and oxidation time:

temperature of 920° C.:

| | 1.0 × 10¹⁶ cm⁻³ | 2.5 × 10²⁰ cm⁻³ |
|---|---|---|
| 60 min | 240 nm | 280 |
| 160 mn | 470 nm | 530 nm |

temperature of 1000° C.:

| | 1.0 × 10¹⁶ cm⁻³ | 2.5 × 10²⁰ cm⁻³ |
|---|---|---|
| 30 min | 240 nm | 280 nm |
| 72 min | 470 nm | 520 nm |

temperature of 1100° C.:

| | 1.0 × 10¹⁶ cm⁻³ | 2.5 × 10²⁰ cm⁻³ |
|---|---|---|
| 12 min | 240 nm | 280 nm |
| 32 min | 430 nm | 500 nm |

temperature of 1200° C.

| | 1.0 × 10¹⁶ cm⁻³ | 2.5 × 10²⁰ cm⁻³ |
|---|---|---|
| 7 min | 270 nm | 310 nm |
| 20 min | 490 nm | 510 nm |

It can be seen that the oxide growth rate depends less on the doping and that this dependency is more marked above 1000° C. than when the doping element is phosphorus.

Silicon dioxide is formed from the silicon of the substrate and the oxygen present in the atmosphere in the oven. Writing the thickness of the oxide layer as e, the interface between silicon and silicon dioxide (Si—SiO₂) presents a setback relative to the top face FS of the substrate SU that is approximately equal to 0.44e.

With reference to FIG. 1b, the left-hand section Sg presents an oxide layer with its top forming a left-hand step Mg and with its base, the Si—SiO₂ interface, forming a left-hand level Ng.

Similarly, the central section Sc presents an oxide layer with its top forming a central step Mc and with its base, the Si—SiO₂ interface, forming a central level Nc.

Finally, the right-hand section Sd presents an oxide layer with its top forming a right-hand step Mg and with its base, the Si—SiO₂ interface, forming a right-hand level Nd.

With reference to FIG. 1c, the calibration device can be used as such since the left-hand step Mg, the central step Mc, and the right-hand step Md are defined very accurately.

With reference to FIG. 1d, it is also possible to etch the oxide. The substrate then presents a left-hand level Ng, a central level Nc, and a right-hand level Nd that are likewise defined very accurately since it is known how to etch SiO₂ with very great selectively relative to silicon.

Naturally, it is not known how to dope a substrate in such a manner that its concentration of dopants is uniform over a required depth and so that this concentration becomes zero beyond that required depth. In reality, this concentration is at a maximum close to the top surface of the substrate and it decreases progressively on going away from said top face. Consequently, the doped silicon conserves some residual doping at the Si—SiO₂ interface. As a result, although the silicon does indeed present zero doping in register with the central level Nc, it presents residual doping in register with the left-hand level Ng that is different from the residual doping in register with the right-hand level Nd.

The various sections Sg and Sd can be doped using any known technique, and in particular by diffusion.

Nevertheless, in a preferred implementation, doping is performed by ion implantation. This technique makes it possible to define accurately the location and the penetration depth of the doping element, which depth can extend over several tens or several hundreds of nanometers (nm).

Furthermore, this technique now benefits from very great accuracy concerning the quantities of ions that are implanted, typically to within 1%. It follows that it is possible to obtain very great accuracy over the rate of growth of the oxide, and above all over the differential rates of growth between two zones that are doped differently, with the differential rate determining the difference in thickness of oxide between the two zones.

With reference to FIG. 2a, a first step of the method of making a device of the invention consists in making a first mask E1 on the substrate SU by a conventional photolithographic technique. The mask E1 is in the form of a strip of resin, of metal, or of any other material that can constitute an inpenetratable barrier for ions during implantation. The mask may possibly be obtained by a direct writing method.

The substrate is subjected to first ion implantation, after which the first mask E1 in removed. It follows that the substrate then presents a first channel C11 where the first mask E1 was present, and a second channel C12 where there was no mask. The quantity applied during the first implantation is such that if the first channel C11 is not doped, the second channel C12 presents phosphorus doping at a concentration of 1.5×10²⁰ cm⁻³.

It should be understood that implantation can deteriorate the top face FS of the substrate, particularly when the ions being implanted are heavy and at relatively low energy. Such implantation parameters lead to the substrates being pulverized, i.e. to its initial layers of atoms being ablated in part. The implantation energy directly determines the penetration depth of the implanted ions, which depth must be adapted to the thickness desired for the thermal oxide. This depth is small in the context of nanotechnology applications. If the implantation energy is about 40 kilo electron volts (kev), the pulverization phenomenon cannot be ignored.

It is therefore preferable, prior to proceeding with implantation, to place a screen on the substrate such as a thin layer of thermal oxide having a thickness of a few tens of nanometers, typically 30 nm. The substrate is thus protected since it is the oxide that is pulverized and not the top face FS of the substrate.

With reference to FIG. 2b, after the first implantation, a second mask E2 is made on the substrate SU. This mask E2 takes the form of two strips, the first covering the left-hand half of the first channel C11, and the second covering the left-hand half of the second channel C12.

The substrate is subjected to second ion implantation, after which the second mask E2 is removed. It follows that the substrate then presents in succession and starting from the left: a first subchannel C101 where both masks E1 and E2 were present; a second subchannel C102 where only the first mask E1 was present; a third subchannel C103 where only the second mask E2 was present; and a third subchannel C104 where no mask has been present.

The quantity of ions applied during the second implantation is that the fourth subchannel C104 is doped with phosphorus to a concentration of 1.65×10²⁰ cm⁻³.

If a screen was placed on the substrate before the first implantation, it is preferable to remove it by etching once the second implantation has been performed.

With reference to FIG. 2c, the substrate SU is then subjected to thermal oxidation at 920° C. for 90 minutes (min), for example.

As explained above, this oxidation produces in succession, starting from the left-hand side of the substrate, first, second, third, and fourth steps M1, M2, M3, and M4 forming a staircase going upwards from the first step M1 to the last step M4.

In register with these steps, there can be seen respectively first, second, third, and fourth levels N1, N2, N3, and N4 that mark the interfaces between the thermal oxide and the silicon of the substrate.

The calibration device can be used carrying its thermal oxide, but it is also possible to etch away the oxide, in which case it is the four levels N1, N2, N3, and N4 that form a staircase going downwards from the first level N1 to the last level N4.

The oxide can be etched using a wet technique or a dry technique. The term “dry” technique covers plasma etching, reactive ion etching, and ion beam etching. Wet etching is particularly recommended in the present example, since it provides a very high level of selectivity between silicon dioxide and silicon.

It can thus be seen that the present invention makes it possible to make a staircase of silicon dioxide or of silicon. If n distinct implantation steps are performed, it is possible to obtain a staircase with 2ⁿ steps or 2ⁿ levels.

By way of example, with reference to FIG. 3, n is equal to 3. Before proceeding with the oxidation following the second implantation in the above-described method, a third mask E3 is made on the substrate SU. This mask E3 takes the form of four strips, the first covering the left-hand half of the first subchannel C101, the second covering the left-hand half of the second subchannel C102, the third covering the left-hand half of the third subchannel C103, and the fourth covering the left-hand half of the fourth subchannel C104.

The substrate is then subjected to third ion implantation, after which the second mask E3 is removed. It follows that the substrate then presents in succession, starting from the left: a first section R1 where all three masks E1, E2, and E3 were present; a second section R2 where only the first and second masks E1 and E2 were present; a third section R3 where only the first and third masks E1 and E3 were present; a fourth section R4 where only the first mask E1 was present; and a fifth, sixth, seventh, and eighth section R5, R6, R7, and R8 where there was no mask.

Naturally, if a screen was present on the substrate before the first implantation, it is preferable not to remove it until the third implantation has been performed.

The substrate SU is then subjected to thermal oxidation.

Above, the steps have been obtained by growing silicon dioxide thermally on the substrate by using oxygen in the growth oven. Under such circumstances, the rate of growth of the layer depends strongly on the doping of the silicon. Nevertheless, the invention would be even more applicable for thin thicknesses if, instead of growing silicon dioxide, it is silicon oxynitride or silicon nitride that is grown. The important point is to produce a layer by thermal growth, where the rate of growth of the layer depends on the doping of the silicon.

Finally, it is appropriate to specify that the maximum number of steps in the staircase is determined by the limits of the techniques used.

The embodiments of the invention described above have been selected for their concrete nature. Nevertheless, it is not possible to list exhaustively all embodiments covered by the invention. In particular, any step or any means described above can be replaced by an equivalent step or means without going beyond the ambit of the present invention.

1. A calibration device on a silicon substrate SU, constituted in addition to a reference level Nc, N4 by at least two distinct levels Ng-ND, N1-N2-N3, and characterized in that said levels present distinct doping concentrations.

2. A device according to claim 1, characterized in that at least one of said levels Ng-Nc-Nd, N1-N2-N3-N4 is surmounted by a step Mg-Mc-Md, M1-M2M3-M4.

3. A device according to claim 2, characterized in that said step Mg-Mc-Md, M1-M2-M3-M4 consists in a layer that was obtained by thermal growth an said substrate SU.

4. A device according to claim 3, characterized in that said layer is made of silicon dioxide.

5. A method of making a calibration device, the method including a definition step of defining at least two sections Sg-Sd, C101-C102-C103, R1-R2-R3-R4-R5-R6-R7 that are distinct from a reference section Sc, S104, R8 on a silicon substrate SU, the method being characterized in that the definition step consists in doping said sections different from said reference section at different concentrations.

6. A method according to claim 5, characterized in that said definition step is preceded by a protection step consisting in covering said substrate SU in a screen.

7. A method according to claim 6, characterized in that said definition step is followed by a step during which said screen is removed.

8. A method according to claim 5, characterized in that the various sections are doped by ion implantation.

9. A method according to, claim 5, characterized in that said definition step is followed by a thermal growth step to produce a coating layer Mg-Mc Md, M1-M2-M3-M4 on said substrate.

10. A method according to claim 9, characterized in that said thermal growth step is followed by a step during which said coating layer Mg-Mc-Md, M1-M2-M3-M4 is removed.

11. A method according to claim claim 9, characterized in that said coating layer Mg-Mc-Md, M1-M2 M3-%4 is made of silicon dioxide.
